(19) United States
(12) Patent Application Publication
(10) Pub. No.: US 2026/0128083 A1
(43) Pub. Date: May 7, 2026

(54) SEMICONDUCTOR MEMORY DEVICE AND OPERATING METHODS OF THE SEMICONDUCTOR MEMORY DEVICE

(71) Applicant: Seoul National University R&DB foundation, Seoul (KR)

(72) Inventor: Cheol Seong Hwang, Seoul (KR)

(21) Appl. No.: 19/377,244

(22) Filed: Nov. 3, 2025

(30) Foreign Application Priority Data
Nov. 5, 2024 (KR) 10-2024-0155482

(51) Int. Cl. G11C 11/4091; G11C 5/06; G11C 11/4074; G11C 11/408; G11C 11/4094

(52) U.S. Cl. CPC G11C 11/4091; G11C 5/063; G11C 11/4074; G11C 11/4085; G11C 11/4094

(57) ABSTRACT

The present disclosure provides a capacitorless semiconductor memory device and a method of driving the capacitorless semiconductor memory device, the disclosed capacitorless semiconductor memory device may include a memory cell array comprising a plurality of memory cells including two transistors; a sensing amplifier and a clamping circuit connected to bit lines of the memory cell array; and a control section for controlling the sensing amplifier, the clamping circuit, and the memory cell array differently according to a first mode or a second mode.

### CROSS-REFERENCE TO RELATED APPLICATION

This application claims priority of Korean Patent Application No. 10-2024-0155482, filed on Nov. 5, 2024, in the KIPO (Korean Intellectual Property Office), the disclosure of which is incorporated herein entirely by reference.

### BACKGROUND OF THE INVENTION

### Field of the Invention

The present invention relates to semiconductor memory technology, and more particularly to a semiconductor memory device and an operating method of the semiconductor memory device.

### Description of the Related Art

Today, a semiconductor memory that randomly writes and reads data at high speed is dynamic random access memory (DRAM), which is widely used in data storage devices or devices. DRAM includes a plurality of repeated memory cells, each of which typically includes a capacitor configured to store data information and a transistor configured to control the reading of data information from the capacitor structure.

To facilitate the integrated development of such memory cells, a related art has developed techniques for using memory cells in a 2T0C structure. The 2T0C structure uses two transistors as memory elements and does not include a capacitor, which reduces the volume occupied by the memory cell. In addition, neighboring memory cells may be organized by sharing word lines and bit lines.

However, these 2T0C DRAMs suffer from the problem that when a selected cell is read, it may be interfered with depending on the state of neighboring cells that share word lines and bit lines. For example, if the selected cell is off (data 0) and the three neighboring cells are all on (data 1), the selected cell has a higher probability of being interfered with by the three neighboring cells.

Therefore, there is a great need to develop a 2TOC circuit that may solve this interference problem between neighboring memory cells. In particular, since DRAM may be used not only as a memory but also as a neuromorphic device for artificial intelligence, according to today's technology trends, it is necessary to develop a 2T0C circuit that may be used without interference from neighboring cells and without data reading errors.

### SUMMARY OF THE INVENTION

The technical problem that the present invention aims to solve is to provide a semiconductor memory device that may read selected cells without interference from neighboring cells and may be used not only for memory but also for neuromorphic devices for artificial intelligence.

Further, another technical problem that the present invention seeks to solve is to provide a method for driving a semiconductor memory device having the aforementioned advantages.

A capacitorless semiconductor memory device according to one embodiment of the present invention includes a memory cell array comprising a plurality of memory cells comprising two transistors, a sensing amplifier and a clamping circuit connected to bit lines of the memory cell array; and a control section for controlling the sensing amplifier, the clamping circuit, and the memory cell array differently according to a first mode or a second mode.

In this case, the clamping circuit applies a clamping voltage value (V_{cl}), which is a value that is a small fraction (δVₜₕ) greater than a difference between an operating voltage value (V_{dd}) of the bit line and a threshold voltage value (Vₜₕ) of the memory cell, to a bit line of the memory cell according to the first mode or the second mode.

Further, the control unit selects at least one of a plurality of read word lines included in the memory cell array in the first mode, and reads data of a plurality of memory cells associated with the selected read word line.

Further, in the first mode, the control part controls a sensing amplifier connected to a bit line of the memory cell array to set a voltage of the bit line to an operating voltage value (V_{dd}) and to change a voltage of the selected read word line to 0 V, thereby reading data of the plurality of memory cells connected to the selected word line.

Further, the capacitorless semiconductor memory device according to one embodiment of the present invention, wherein in the first mode, the clamping circuitry causes the minimum value of the voltage on the bit line to be the clamping voltage value.

The capacitorless semiconductor memory device according to the present invention, characterized in that in the second mode, the control portion selects at least one of the plurality of memory cells, and controls that an operating voltage value (V_{dd}) is applied to the bit lines associated with the selected memory cell, and that a clamping voltage value (V_{cl}) of the clamping circuit is applied to the bit lines of the unselected memory cell to read data from the selected memory cell.

Further, the capacitorless semiconductor memory device according to one embodiment of the present invention is characterized in that in the second mode, the voltage of the selected word line is varied to 0 V, and an operating voltage value (V_{dd}) is applied to the unselected word line.

In this case, the voltage drop of the unselected memory cell is not exceeded by the threshold voltage value by the clamping voltage value.

Further, a method for driving a memory cell array comprising a plurality of memory cells comprising two transistors according to one embodiment of the present invention, wherein the memory cell array is connected with a sensing amplifier and a clamping circuit via bit lines, and wherein the control part selects a first mode or a second mode depending on which memory cell of the memory cell array is selected for reading data; and, in accordance with the selected first mode or second mode, reading data from the memory cell using at least one of an operating voltage value (V_{dd}) provided by the sensing amplifier and a clamping voltage value (V_{cl}) provided by the clamping circuit, wherein the clamping voltage value is set to a value a predetermined amount (δVₜₕ) greater than a difference between the operating voltage value (V_{dd}) and a threshold voltage value (Vₜₕ) of the memory cell.

In this case, the step of reading data from the memory cell includes, at the first mode selection, controlling a sensing amplifier connected to a bit line of the memory cell to read the data to set the voltage of the bit line to an operating voltage value (V_{dd}) and changing the voltage of a word line of the memory cell to read the data to 0 V to read the data of a plurality of memory cells connected to the selected word line.

Further, the clamping circuitry causes a minimum value of the voltage on the bit line in the first mode to be the clamping voltage value.

Further, the step of reading data from the memory cells comprises, in the second mode, selecting at least one of the plurality of memory cells, and controlling the sensing amplifier to apply an operating voltage value (V_{dd}) to the bit lines associated with the selected memory cell, and controlling the clamping circuit to apply a clamping voltage value (V_{cl}) to the bit lines of the unselected memory cell, thereby reading data from the selected memory cell.

Further, in the second mode, the voltage of the selected word line is varied to 0V, and an operating voltage value (V_{dd}) is applied to the unselected word line, so that the voltage drop of the unselected memory cell is not exceeded by the clamping voltage value to the threshold voltage value.

According to embodiments of the present invention, by using a semiconductor memory device having a structure in which a capacitor is excluded, a semiconductor memory device that is effective in reading only data in a selected memory cell, and that has improved reliability by using a clamping circuit to set a clamping voltage to a specific memory cell, thereby preventing leakage current and enabling error-free reading of data from the desired memory cell, may be provided.

Furthermore, according to an embodiment of the present invention, by resetting the clamping voltage in a voltage clamping circuit of a sensing amplifier disposed in each cell, a method of driving a semiconductor memory device that may be used in a neuromorphic device for artificial intelligence by excluding interference from neighboring cells in a 2T0C DRAM device and accurately reading only data in a selected memory cell may be provided.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates an embodiment of a capacitorless semiconductor device including two transistors according to the present invention.

FIG. 2 illustrates an embodiment of a memory cell array including a plurality of memory cells.

FIG. 3 illustrates an embodiment of a semiconductor memory device according to the present disclosure operating in a first mode.

FIG. 4 illustrates an embodiment in which a semiconductor memory device according to the present invention operates in a second mode.

FIG. 5 is a flow diagram illustrating a method of driving a memory cell array comprising a plurality of memory cells including two transistors, according to one embodiment of the present disclosure.

In the following description, the same or similar elements are labeled with the same or similar reference numbers.

### DETAILED DESCRIPTION

The present invention now will be described more fully hereinafter with reference to the accompanying drawings, in which embodiments of the invention are shown.

This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

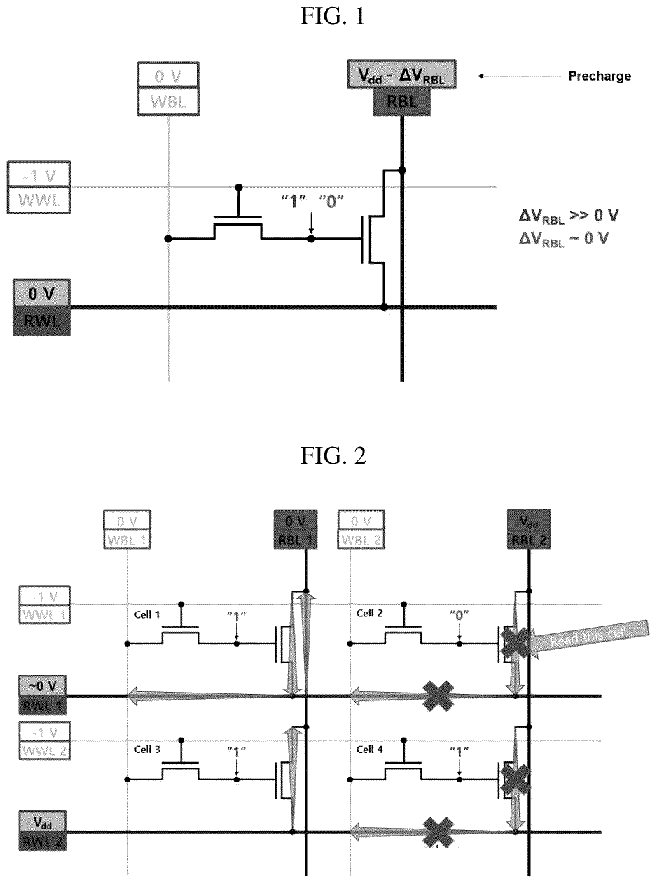

FIG. 1 is a drawing illustrating one embodiment of a capacitorless semiconductor device including two transistors according to the present disclosure.

Referring to FIG. 1, a capacitorless semiconductor device including two transistors according to one embodiment of the present invention includes a transistor for data writing operation and a transistor for reading operation. The transistor for data writing operation has a drain region connected to a word bit line (WBL) and a control electrode connected to a write word line (WWL). The transistors for data read operation have a source region connected to the read bit line (RBL) and a drain region connected to the read word line (RWL).

The data read operation of such a memory cell array is described as follows. During a data read operation, the semiconductor memory device first sets the bit line (SRBL) of the selected memory cell to the operating voltage (V_{dd}) i.e., precharges and floats the current so that the bit line of the selected memory cell has the operating voltage value (V_{dd}).

Next, the voltage of the read word line (RWL) of the selected memory cell is set to 0V, and the data stored in the selected memory cell is read from the change in the bit line voltage (ΔV_{RBL}) of the selected memory cell. If the data of the selected memory cell is 0, the bit line voltage change (ΔV_{RBL}) remains close to 0. Conversely, if the data is 1, a voltage drop occurs within a period of time.

FIG. 2 is a diagram illustrating an embodiment of a memory cell array including a plurality of memory cells. Referring to FIG. 2, a read word line (RWL) associated with a memory cell selected for reading data from the plurality of memory cells is set to 0 V, and another read word line (RWL) is set to an operating voltage (V_{dd}) For example, when the selected memory cell is cell 2, the read word line RWL 1 associated with cell 2 is set to 0 V, and the other read word line (RWL 2) is set to the operating voltage (V_{dd}).

By using a memory cell containing these two transistors and not including a capacitor, it is possible to separate the read and write operations, which, when configured as an array containing multiple memory cells, has the effect of increasing efficiency because only the required data may be read and transferred to buffer memory.

On the other hand, leakage current may occur depending on the state of the word line of the selected memory cell and the neighboring memory cells that share the bit line. For example, if the data of the selected memory cell (cell 2) is 0, but the data of the three neighboring memory cells (cells 1, 3, and 4) is 1, leakage current may occur between the memory cells, which may interfere with the reading of the selected memory cell.

To solve the problem of interference caused by such leakage current, the present invention presents an embodiment in which a sensing amplifier and a clamping circuit are connected to the read bit line of a memory cell, and the operation of the sensing amplifier and the clamping circuit is controlled according to the data reading mode.

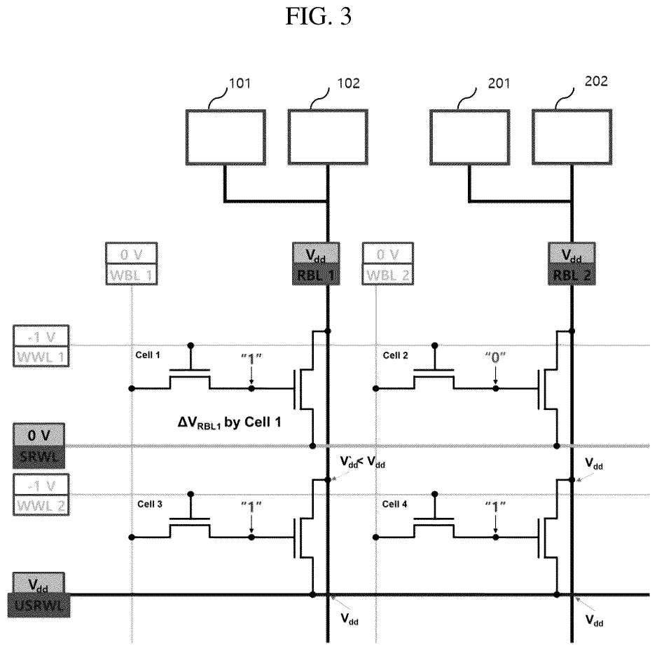

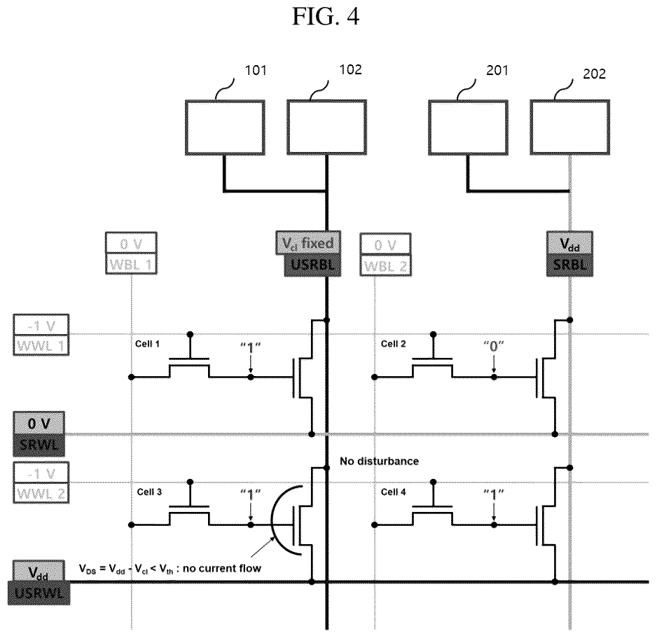

FIGS. 3 and 4 are drawings illustrating a configuration of connecting a sensing amplifier and a clamping circuit to a read bit line of a memory cell, according to one embodiment of the present invention.

A semiconductor memory device according to one embodiment of the present disclosure includes a plurality of memory cells and includes a sensing amplifier 102, 202 and clamping circuitry 101, 201 connected to a read bit line (RBL) of each memory cell.

Furthermore, the semiconductor memory device according to one embodiment of the present invention operates in a first mode (page mode) that reads data of a plurality of memory cells connected to a selected word line all at once and a second mode (random access mode) that reads data of a particular memory cell only, and implements different operations of the clamping circuitry (101, 201) according to each mode.

That is, the semiconductor memory device according to one embodiment of the present invention may select either the first mode or the second mode, and in the first mode, the clamping circuitry may set the clamping voltage value to be the minimum value of the voltage applied to the read bit line, and in the second mode, the clamping circuitry may control that the clamping voltage value is applied to the bit line corresponding to the unselected memory cell.

FIG. 3 is a diagram illustrating an embodiment in which a semiconductor memory device according to the present disclosure operates in the first mode.

Referring to FIG. 3, the semiconductor memory device of the present invention determines whether the plurality of memory cells are to be operated in the first mode or the second mode in a control section (not shown), and in the case of determining that the plurality of memory cells are to be operated in the first mode, operates the sensing amplifiers 102, 202 connected to the read bit lines of the memory cell to be read out of the plurality of memory cells to set the voltage of the read bit line to an operating voltage (V_{dd}) (precharge-floating), and sets the voltage of the selected read word line to 0V.

Thus, the semiconductor memory device according to one embodiment of the present disclosure may read data from the selected memory cells, i.e., a plurality of memory cells connected to the selected word lines, at once by dropping the voltage of each selected read bit line in the first mode.

For example, in FIG. 3, the semiconductor memory device of the present invention may read data 1 of cell 1 and data 0 of cell 2 by dropping the SRWL voltage to 0 V.

On the other hand, the semiconductor memory device according to one embodiment of the present invention applies an operating voltage (V_{dd}) to the read word lines of the unselected memory cells so that no current flows to the unselected memory cells regardless of the data value of the unselected memory cells.

However, even in this case, if a non-selected memory cell that shares a read bit line to which the operating voltage is applied is in the data 1 state, the transistor for the read operation of the non-selected memory cell will be subjected to voltage over time, and leakage current will flow, causing the selected bit line voltage to not operate exactly as the operating voltage.

To solve these problems, the semiconductor memory device according to one embodiment of the present invention connects the clamping circuits 101, 201 in parallel to the sensing amplifiers 102, 202 so that the voltage of the read bit line does not fall below a clamping voltage value (V_{cl}), clamping voltage) in the first mode.

In this case, the clamping circuitry 101, 201 ensures that the clamping voltage value (V_{cl}), which is a value that is a predetermined amount (δVₜₕ) greater than the difference between the operating voltage value (V_{dd}) of the bit line and the threshold voltage value (Vₜₕ) of the memory cell, is the voltage minimum of the read bit line.

For example, if V_{dd}=1 V, Vₜₕ=0.4 V, and δVₜₕ=0.1 V, then V_{cl}=V_{dd}−Vₜₕ+δVₜₕ=1-0.4+0.1=0.7 V. The predicate (δVₜₕ) may be set to one of various values depending on the implementation embodiment.

Thus, according to the present invention, since the minimum value of the voltage value (V_{RBL})on the bit line is fixed at V_{cl,} the maximum voltage value (V_{GS}) across the nonselect memory cell occurs when the non-select memory cell is in the state of data 1, The value is V_{dd}−V_{cl} =V_{dd}−(V_{dd}−Vₜₕ+δVₜₕ)=Vₜₕ−δVₜₕ, which is set to be lower than the threshold voltage value Vₜₕ of the non-selected memory cell. If the unselected memory cell is in the data zero state, the voltage applied to the control electrode of the transistor for the read operation is 0V, which is always less than the voltage across the source terminal and the voltage across the drain terminal, so no current may flow.

Therefore, in accordance with one embodiment of the present invention, setting a minimum value of the bit line voltage with the clamping circuit in the first mode has the effect of preventing current flow from the word line of the non-select memory cell to the read bit line, thereby solving the problem of malfunction caused by leakage current.

FIG. 4 is a diagram illustrating an embodiment in which a semiconductor memory device according to the present disclosure operates in a second mode.

Referring to FIG. 4, the semiconductor memory device of the present invention determines whether the plurality of memory cells are to be operated in the first mode or the second mode in the control section (not shown), and when it is determined that the plurality of memory cells are to be operated in the second mode, the sensing amplifier 202 connected to the read bit line of the memory cell to be read from among the plurality of memory cells is operated to set the voltage of the read bit line to the operating voltage (V_{dd}) (precharge-floating), and the voltage of the read word line (SRWL) connected to the selected memory cell is changed to 0 V. Thus, according to one embodiment of the present invention, the semiconductor memory device of the present invention may only read data from the selected memory cell in the second mode by lowering the voltage to the transistor for the read operation of the selected memory cell.

Further, when the second mode is selected, the semiconductor memory device according to one embodiment of the present invention drives the clamping circuit 101 to apply a clamping voltage value (V_{cl}) to the bit lines of the unselected memory cell.

Further, the semiconductor memory device according to one embodiment of the present invention applies an operating voltage value (V_{dd}) to the read word line (USRWL) of the unselected memory cell when the second mode is selected.

Thus, according to one embodiment of the present invention, the voltage drop of the unselected memory cell is not exceeded by the threshold voltage value by the clamping voltage value, so that no current flows, and no problem caused by leakage current occurs.

In other words, if the clamping voltage value is set to a value (δVₜₕ) larger than the difference between the operating voltage value (V_{dd}) and the threshold voltage value (Vₜₕ) of the memory cell as in the above embodiment, even if the unselected memory cell 3 is in the state of data 1, the voltage applied to the memory cell 3 becomes the operating voltage (V_{dd}) applied to the read word line-the pre-clamping value (V_{cl}), V_{dd}−V_{cl}=V_{dd}−(V_{dd}−Vₜₕ+δVₜₕ)=Vₜₕ−δVₜₕ, which is set to be lower than the threshold voltage value (Vₜₕ) of the corresponding non-selected memory cell, so that no leakage current flows, thereby solving the problem of malfunction caused by leakage current.

Thus, according to embodiments of the present invention, by using a semiconductor memory element having a structure in which a capacitor is excluded, a semiconductor memory element having improved reliability may be provided that is effective in reading only data in a selected memory cell, and by setting a clamping voltage to a specific memory cell using a clamping circuit, leakage current may be prevented and data may be read without error from the desired memory cell.

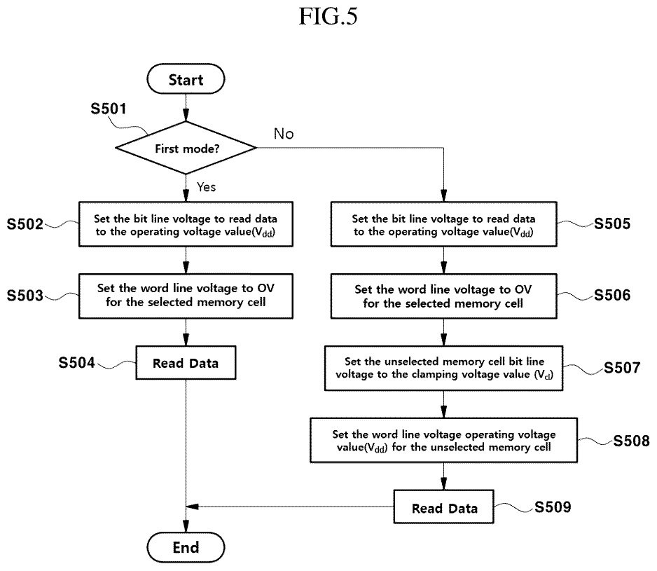

FIG. 5 is a flow diagram illustrating a method of driving a memory cell array comprising a plurality of memory cells including two transistors, according to one embodiment of the present disclosure.

The driving method of FIG. 5 is performed by a device comprising a memory cell array comprising a plurality of memory cells comprising two transistors and excluding a capacitor as described above, the memory cell array being connected via bit lines to a sensing amplifier and clamping circuitry.

In step S501, the semiconductor memory device control unit according to one embodiment of the present invention selects a first mode or a second mode depending on the memory cell selected for reading data from the memory cell array. As described above, it operates in a first mode (page mode) that reads data of a plurality of memory cells connected to the selected word line at once and a second mode (random access mode) that reads data of only a specific memory cell, and implements different clamping circuit operations according to each mode.

When it is determined that the reading operation of the memory cell is in the first mode as a result of the judgment in step S501, the control part operates the sensing amplifiers 102, 202 connected to the read bit lines of the memory cell to be read out of the plurality of memory cells in step S502 to set the voltage of the read bit line to the operating voltage (V_{dd}) (precharge-floating), and sets the voltage of the selected read word line to 0 V in step S503.

Thus, the semiconductor memory device according to one embodiment of the present invention may read the data of the selected memory cells, i.e., the plurality of memory cells connected to the selected word lines, at once by dropping the voltage of each selected read word line in the first mode.

Also, as described above, in the first mode, the clamping circuits 101, 201 are connected in parallel to the sensing amplifiers 102, 202 so that the voltage of the read bit lines does not fall below a clamping voltage value (V_{cl}, clamping voltage), and the clamping circuits (101, 201) so that the clamping voltage value (V_{cl}), which is a value that is a predetermined amount (δVₜₕ) greater than the difference between the operating voltage value (V_{dd}) of the bit line and the threshold voltage value (Vₜₕ) of the memory cell, is the voltage minimum of the read bit line.

For example, if V_{dd}=1 V, Vₜₕ=0.4 V, and δVₜₕ=0.1 V, then V_{cl} may be 0.7 V. δVₜₕ may be set to one of various values depending on the implementation embodiment.

Thus, since the minimum value of the voltage value on the bit line (V_{RBL}) is fixed at V_{cl,} the maximum voltage value across the transistor for a read operation of the non-select memory cell (V_{GS}) occurs when the non-select memory cell is in the data 1 state, The value is V_{dd}−V_{cl}=V_{dd}−(V_{dd}−Vₜₕ +δVₜₕ)=Vₜₕ−δVₜₕ, which is set to be lower than the threshold voltage value (Vₜₕ) of the transistor for the read operation of the non-select memory cell. If the non-selective memory cell is in the data 0 state, the voltage applied to the control electrode of the transistor for the read operation is 0V, and the source terminal voltage and the drain terminal voltage are larger, so the current might not always flow.

Therefore, in accordance with one embodiment of the present invention, setting a minimum value of the bit line voltage with the clamping circuit in the first mode has the effect of preventing current flow from the word line of the non-select memory cell to the read bit line, thereby solving a malfunction problem caused by leakage current.

If, as a result of the judgment in step S501, the control determines that the plurality of memory cells are to be operated in the second mode, the control operates the sensing amplifier 202 connected to the read bit line of the memory cell to be read out of the plurality of memory cells in step S505 to set the voltage of the read bit line to the operating voltage (V_{dd}) (precharge-floating), and the voltage of the read word line (SRWL) connected to the selected memory cell is changed to 0 V in step S507. Thus, according to one embodiment of the present invention, the semiconductor memory device of the present invention may drop the voltage of the read word line to the selected memory cell in the second mode, so that only the data of the selected memory cell may be read.

Next, in step S507, the semiconductor memory device according to one embodiment of the present invention drives the clamping circuit 101 to apply a clamping voltage value (V_{cl}) to the bit lines of the unselected memory cell.

Next, in step (S508), the semiconductor memory device according to one embodiment of the present invention applies an operating voltage value (V_{dd}) to the read word line (USRWL) of the unselected memory cell when the second mode is selected, and reads the data of the selected memory cell in step S509.

Accordingly, according to one embodiment of the present invention, the voltage drop of the unselected memory cell is not exceeded by the threshold voltage value by the clamping voltage value so that no current flows and no problem caused by leakage current occurs. That is, as in the above embodiment, when the clamping voltage value is set to a value that is a small percentage (δVₜₕ) larger than the difference between the operating voltage value (V_{dd}) and the threshold voltage value (Vₜₕ) of the memory cell, Even if the unselected memory cell 3 is in the state of data 1, the voltage applied to the transistor for the read operation of the memory cell 3 becomes the operating voltage (V_{dd}) applied to the read word line (V_{dd})−the value before clamping voltage value (V_{cl}), V_{dd}−V_{cl}=V_{dd}−(V_{dd}−Vₜₕ+δVₜₕ)=Vₜₕ−δVₜₕ, which is set lower than the threshold voltage value (Vₜₕ) of the corresponding non-selected memory cell, so that no leakage current flows, thereby solving the problem of malfunction caused by leakage current.

The semiconductor memory device and the operation method of the semiconductor memory device according to one embodiment of the present invention may be used not only for memory but also for neuro informatics devices for artificial intelligence, and may be used in the field of VMM (Vector Matrix Multiplication) technology, as selected cells may be read without interference from neighboring cells. In other words, according to an embodiment of the present invention, as described above, by resetting the clamping voltage in the voltage clamping circuit of the sensing amplifier arranged in each cell, the interference of neighboring cells in the 2T0C DRAM device is excluded and only the data of the selected memory cell is accurately read, maximizing the effect when applied to a neuromorphic device for artificial intelligence.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A capacitorless semiconductor memory device, comprising:
a memory cell array comprising a plurality of memory cells including two transistors;
a sensing amplifier and a clamping circuit connected to bit lines of the memory cell array; and
a control section for controlling the sensing amplifier, the clamping circuit, and the memory cell array differently according to a first mode or a second mode.

2. The device of claim 1, wherein the clamping circuit applies a clamping voltage value (V_{cl}), which is a value predetermined (δVₜₕ) greater than a difference value between an operating voltage value (V_{dd}) of the bit line and a threshold voltage value (Vₜₕ) of the memory cell, to a memory cell of the bit line according to the first mode or the second mode.

3. The device of claim 2, wherein the control portion selects at least one of a plurality of read word lines included in the array of memory cells in the first mode, and reads data of a plurality of memory cells associated with the selected read word line.

4. The device of claim 3, wherein the control portion controls a sensing amplifier connected to a bit line of the memory cell array in the first mode to set a voltage of the bit line to an operating voltage value (V_{dd}), and to change a voltage of the selected read word line to 0 V, thereby reading data of a plurality of memory cells connected to the selected word line.

5. The device of claim 4, wherein in the first mode, the clamping circuitry causes a minimum value of the voltage on the bit line to be the clamping voltage value.

6. The device of claim 2, wherein the control portion selects at least one of the plurality of memory cells in the second mode, and reads data from the selected memory cell by controlling that an operating voltage value (V_{dd}) is applied to a bit line associated with the selected memory cell, and that a clamping voltage value (V_{cl}) of the clamping circuit is applied to a bit line of the unselected memory cell.

7. The device of claim 6, wherein in the second mode, the voltage of the selected word line is changed to 0 V, and an operating voltage value (V_{dd}) is applied to the unselected word line.

8. The memory device of claim 7, wherein the voltage drop of the unselected memory cell is not exceeded by the threshold voltage value by the clamping voltage value.

9. A method of driving a memory cell array comprising a plurality of memory cells including two transistors, comprising:
selecting a first mode or a second mode according to a selected memory cell in order to real data among memory cell arrays by a control unit, the memory cell arrays connected to a sensing amplifier and a clamping circuit through a bit line; and
reading data from the memory cell using at least one of an operating voltage value (V_{dd}) provided by the sensing amplifier and a clamping voltage value (V_{cl}) provided by the clamping circuit, according to the selected first mode or second mode,
wherein the clamping voltage value is set to a value predetermined (δVₜₕ) greater than a difference value between the operating voltage value (V_{dd}) and a threshold voltage value (Vₜₕ) of the memory cell.

10. The method of claim 9, wherein the step of reading data from the memory cell reads data from a plurality of memory cells connected to the selected word line is performed by controlling a sensing amplifier connected to a bit line of the memory cell from which the data is to be read by setting a voltage of the bit line to an operating voltage value (V_{dd}), and changing a voltage of a word line of the memory cell from which the data is to be read to 0 V, when the first mode is selected.

11. The method of claim 10, wherein the clamping circuitry causes a minimum value of a voltage on the bit line in the first mode to be a value of the clamping voltage.

12. The method of claim 9, wherein the step of reading data from the memory cell selects at least one of the plurality of memory cells in the second mode, and reads data from the selected memory cell by controlling the sensing amplifier to apply an operating voltage value (V_{dd}) to bit lines associated with the selected memory cell, and controls the clamping circuit to apply a clamping voltage value (V_{cl}) to bit lines of the unselected memory cell.

13. The method of claim 12, wherein, in the second mode, a voltage of the selected word line is varied to 0 V, and an operating voltage value (V_{dd}) is applied to the unselected word line, such that a voltage drop of the unselected memory cell is not exceeded by the threshold voltage value by the clamping voltage value.
